(19) United States
(12) Patent Application Publication
(10) Pub. No.: US 2016/0138516 A1
(43) Pub. Date: May 19, 2016

(54) METHOD FOR PRODUCING AN OXIDATION PROTECTION LAYER FOR A PISTON FOR USE IN INTERNAL COMBUSTION ENGINES AND PISTON HAVING AN OXIDATION PROTECTION LAYER

(71) Applicant: KS KOLBENSCHMIDT GMBH, Neckarsulm (DE)

(72) Inventor: Herbert Moding, Bad Friedrichshall (DE)

(73) Assignee: KS Kolbenschmidt GMBH, Neckarsulm (DE)

(21) Appl. No.: 14/898,382

(22) PCT Filed: Jun. 13, 2014
(86) PCT No.: PCT/EP2014/062382

§ 371 Date: Dec. 14, 2015

(30) Foreign Application Priority Data
Jun. 14, 2013 (DE) 10 2013 211 079.0

(51) Int. Cl. F02F 3/12; C23C 14/16; C23C 14/08; C23C 4/11; C23C 8/18; C23C 16/06; C23C 16/40; B05D 1/18; C25D 11/34; C23C 8/14; C23C 4/08; C23C 14/24

(52) U.S. Cl. CPC F02F 3/12; C23C 4/08; C23C 14/16; C23C 14/081; C23C 4/11; C23C 14/085; C23C 14/24; C23C 16/06; C23C 16/403; C23C 16/406; B05D 1/18; C25D 11/34; C23C 8/14; C23C 8/18

(57) ABSTRACT

A piston, especially a steel piston for an internal combustion engine, has a piston head which forms part of a combustion chamber. At least the piston head has an oxidation protective layer. A method for producing an oxidation protection layer is disclosed.

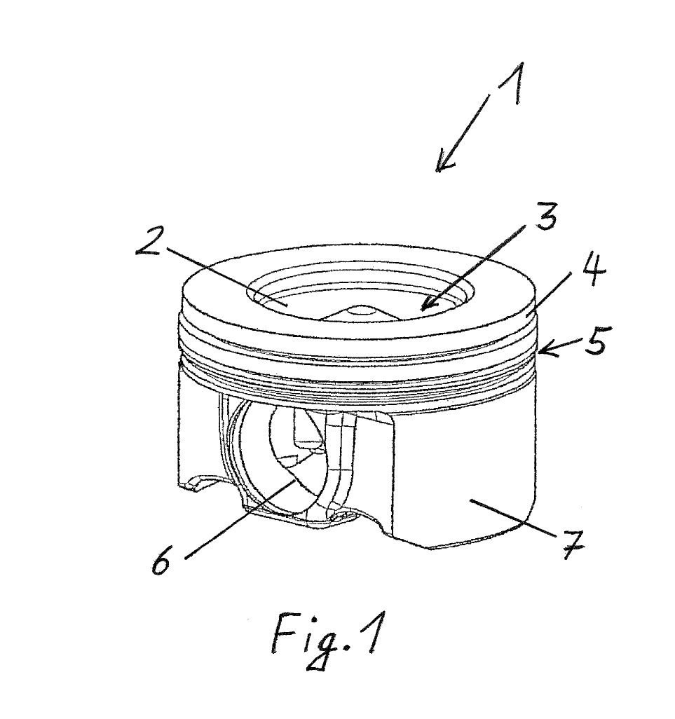

### BACKGROUND

The disclosure relates to processes for producing an oxidation protection layer for at least the region of the piston crown of a steel piston for internal combustion engines and also to piston having an oxidation protection layer.

A forged piston is known, for example, from DE 103 11 150 A1. There, a description is given of the piston made up of a first semifinished part having at least one flat end face composed of oxidation-resistant steel and a second cylindrical semifinished part which has at least one flat end face and is composed of a hot-forgeable steel. The two semifinished parts are combined by forging to give a piston blank. The finished piston thus consists of the oxidation-resistant steel in the region of the piston head except for the first piston ring groove.

The use of oxidation-resistant steels for the combustion chamber region of pistons is known from the prior art.

It is desirable to ensure or at least to significantly improve the protection of the combustion chamber region of steel pistons against oxidation processes.

### SUMMARY

As a result of the oxidation protection layer of the present process, oxidation processes are avoided during engine operation and an improved thermal shock resistance is achieved. A pseudomonolithic piston is formed.

An oxidation protection layer is, for example, produced by physical deposition of the coating materials from the gas phase (physical vapor deposition—PVD). Here, the coating materials are brought into the gas phase by physical processes and are then later deposited therefrom onto the substrate. While in the case of a process for deposition of an oxidation protection layer on the surface of a piston for internal combustion engines by means of the PVD technique the coating material is generally vaporized in solid form and optionally with introduction of heat, in the CVD technique the coating materials are introduced in the gas phase.

As an alternative or in addition, chemical vapor deposition (CVD) can be used as a process for depositing an oxidation protection layer on the surface of a piston. In this surface coating technique, the coating materials are brought into the vapor phase by means of chemical processes and are then deposited therefrom onto the substrate. The coating of the combustion chamber region as a substrate can, for example, be achieved with previous bonding layer-free gas or plasma nitriding. Here, layer thicknesses of 3-20 μm are sought; and layer thicknesses of 5 μm can be sought. Furthermore, it is possible to use Al—Cr—Ti nitrides (aluminum-chromium-titanium nitrides) or carbides, which have a high thermal shock resistance, as layer materials. Homogeneous, defined oxidation protection layers can be produced by deposition of the coating materials from the gas or vapor phase onto the piston surface.

The deposition of the oxidation protection layer on the piston surface can alternatively also be effected by means of pulsed laser ablation (PLD—pulsed laser deposition). In this process, high-energy and short-wavelength (UV) light is used in order to bring the starting material (solid target) into the gas phase and via this bring it in the form of a layer onto the piston surface to be coated (substrate). Laser ablation also belongs to the class of physical vapor deposition processes (PVD processes).

The application of oxidation protection layers on piston surfaces can alternatively also be carried out by the Plasmaimpax® process. This utilizes high-energy particles and a high-voltage pulse technique for 3-dimensional modification and coating of surfaces. The Plasmaimpax process makes it possible to deposit a layer from the gas phase by means of plasma sources under reduced pressure. It is a hybrid technique made up of plasma-activated low-temperature CVD and ion implantation. To increase the surface hardness and also the wear and corrosion resistance, ion implantation processes and ion-assisted coating processes can be carried out using this environmentally friendly technology. Here, low coating temperatures are sufficient to successfully achieve deposition of a layer and surface modification.

The Plasmaimpax technology also enables protective layers based on diamond-like carbon (DLC) to be applied and also surface modifications to be carried out by ion implantation in order to increase the surface hardness. The diamond-like carbon layers have a high chemical resistance (corrosion resistance).

The deposition of the oxidation protection layer on the piston surface can alternatively also be carried out by plasma-assisted chemical vapor deposition (PECVD or PACVD—plasma assisted (enhanced) physical vapor deposition). For example, in order to produce carbon layers, acetylene (C₂H₂), or to produce silicon-containing layers, HMDSO (hexamethyldisiloxane) can be introduced and be cracked in the plasma and thus made available for coating. In the PACVD technique, low operating temperatures are possible.

For the purposes of the present disclosure, the processes mentioned below for producing an oxidation protection layer on the surface of a piston for internal combustion engines by physical processes for the deposition of coating materials from the gas phase (physical vapor deposition—PVD) include classical PVD and also pulsed laser ablation (PLD—pulsed laser deposition).

For the purposes of the present disclosure, the processes mentioned below for producing an oxidation protection layer on the surface of a piston for internal combustion engines using chemical vapor deposition (CVD) include Plasmaimpax® processes and plasma-assisted chemical vapor deposition.

As an alternative or in addition, electrochemically applied coatings comprising nickel, nickel-based alloys, chromium, chromium-based alloys, scale-resistant Fe-based alloys (iron-based alloys) or tungsten alloys and molybdenum alloys are used for forming an oxidation protection layer. In electrochemical coating, layer thicknesses of 5-100 μm are deposited, and particularly to 5-20 μm being deposited on the substrate.

In electrochemical processes for producing an oxidation protection layer on the surface of a piston for internal combustion engines, metallic deposits (coatings) are electrochemically deposited on substrates (objects) and an electrochemical coating is formed on the piston or the piston surface. The electrochemical processes are among the processes for electrochemical metal deposition (ECD—electrochemical deposition). As an alternative, the ECD processes serve to produce an oxidation protection layer on the surface of a piston for internal combustion engines. Electrochemical metal deposition enables metal layers to be produced as oxidation protection layer on the surface of the piston by a reliable process. Electrochemical processes are suitable for the formation of oxidation protection layers because of the relatively small outlay in terms of apparatus.

As an alternative or in addition, cladding processes can also be employed as processes for producing an oxidation protection layer on the surface of a piston for internal combustion engines. In cladding, at least two materials are joined by plastic deformation under pressure. At least one material forms the oxidation protection layer on the piston surface.

As an alternative or in addition, an oxidation protection layer is formed on the substrate by application of a layer by thermal spraying (plasma, HVOF, flame-spraying processes) and, depending on requirements (adhesion, gastightness), is densified and metallurgically bound by means of electron beam, WIG processes, etc. (materials groups similar to electrochemical coating). Steels having high chromium, silicon and aluminum contents (Cr, Si and Al contents) form very impermeable oxide layers which protect the material against further oxidation.

Thermal spraying processes can alternatively be used for producing an oxidation protection layer on the surface of a piston for internal combustion engines.

Thermal spraying is a universally applicable surface coating process in which a coating material, which is usually in powder or wire form, is thrown with high thermal and/or kinetic energy onto a component surface and there forms a layer. The many process variants available enable a broad spectrum of materials, e.g. metals and ceramics and also high-performance polymers, to be processed to give industrial coatings. The layer thicknesses range from about 30 μm to a number of millimeters.

Thermal spraying encompasses the following processes for producing an oxidation protection layer on the surface of a piston for internal combustion engines: wire or rod flame spraying, powder flame spraying, polymer flame spraying, high-velocity flame spraying (HVOF—high velocity oxygen fuel), detonation spraying or flame shock spraying, plasma spraying, laser spraying, electric arc spraying, cold gas spraying and plasma application welding (PTA—plasma transfer arc).

Thermal spraying processes can be used with a wide variety of coating materials, so that the oxidation protection layer on the piston crown can be varied quickly, depending on the respective requirements.

In wire or rod flame spraying, the spraying additive material is continuously melted in the center of an acetylene-oxygen flame. With the aid of an atomizer gas, for example compressed air or nitrogen, the droplet-like spray particles are detached from the melt region and flung onto the prepared piston surface.

In powder flame spraying, the pulverulent spray additive is partially melted or melted in an acetylene-oxygen flame and flung with the aid of the expanding combustion gases onto the prepared piston surface.

If necessary, an additional gas, for example, argon or nitrogen, can also be used for accelerating the powder particles. The variety of spray additive materials is very wide in the case of powders, with far over 100 materials.

Among the powders, a distinction is made between free-flowing and self-adhering powders. Free-flowing powders usually require an additional thermal after-treatment. This “melting-in” is carried out predominantly using acetylene-oxygen burners. If a thermal after-treatment is carried out, this is a multistage process for producing an oxidation protection layer on the surface of a piston for internal combustion engines.

The thermal process considerably increases the adhesion of the sprayed layer on the base material and the sprayed layer becomes impermeable to gas and liquid.

Polymer flame spraying differs from the other flame spraying processes in that the polymer additive does not come into direct contact with the acetylene-oxygen flame. A powder conveying nozzle is located in the middle of the flame spraying gun. This is surrounded by two annular nozzle exits, with the inner ring being for air or an inert gas and the outer ring being for the thermal energy carrier, viz. the acetylene-oxygen flame.

The melting process of the polymer thus is not effected directly by the flame; but instead by means of the heated air and radiated heat.

Metal powders, metal powder alloys, ceramic powders and polymer powders, for example, can be processed by flame spraying or powder flame spraying.

The NiCrBSi coating (nickel-chromium-boron-silicon coating) is a surface finish applied by flame spraying for increasing the oxidation resistance of the piston surface. A coating composed of NiCrBSi alloy is very corrosion-resistant.

The proportion of nickel in the coatings is in the range 40-90%. The proportion of chromium in the coating is in the range 3-26% and gives the layers their hardness.

The NiCrBSi coating is, for example, applied by powder flame spraying with subsequent melting-in/sintering-in.

Base materials processed are steel and stainless steels. The components are, for example, heat treated to dissipate stresses, coarsely particle-blasted and coated immediately afterward in order to avoid corrosion underneath.

The NiCrBSi powder is sprayed on by means of a flame spraying gun and then melted-in by means of an autogenous hand torch, inductively or in a vacuum furnace at about 1000° C.

The NiCrBSi coating is visible as a “wet sheen” during the melting-in process. This “wet sheen” is very plastic at about 1000° C. and the process is therefore carried out in such a way that the melt does not run down or drip from the component, and thus make the NiCrBSi coating defective.

This high coating technology of the NiCrBSi coating is, as the only one of the thermally sprayed layers, gastight without additional sealing techniques and is also best able among all flame-spray coatings to resist impacts because of diffusion into the base material.

The additive WC/Ni makes the hard metal coating (NiCrBSi coating) significantly more corrosion-resistant, with WC/Co having a higher heat resistance.

PTFE or graphite can also be mixed into the alloy. As a result, this hard metal coating acquires better antiadhesion and sliding properties.

In the case of high-velocity flame spraying (HVOF), continuous gas combustion takes place at high pressures within a combustion chamber into the central axis of which the pulverulent spraying additive is introduced. The high pressure of the fuel gas-oxygen mixture generated in the combustion chamber and the usually downstream expansion nozzle produce the desired high flow velocity in the gas jet. In this way, the spray particles are accelerated to the high particle velocities which lead to tremendously impermeable sprayed layers having excellent adhesion properties. Due to the sufficient but moderate introduction of heat, the spraying additive material is altered only slightly in metallurgical terms by the spraying process, e.g. minimal formation of mixed carbides. In this process, extremely thin layers having high dimensional accuracy can be produced.

As fuel gases, it is possible to use propane, propene, ethylene, acetylene and hydrogen.

Carbidic materials can, for example, be applied to the surface of a piston for internal combustion engines by means of high-velocity flame spraying (HVOF) as process for producing an oxidation protection layer. The layers which form on the piston surface are very impermeable. Due to the high hardness of the carbide layers, they represent excellent wear and oxidation protection for the piston. For example, the following materials, chromium carbides (Cr3C2, Cr3C2/NiCr) or tungsten carbides (WC/Co, WC/Ni, WC/Co/Cr), are used.

Detonation spraying or flame shock spraying is an intermittent spraying process. The detonation gun consists of an exit tube at the end of which a combustion chamber is located. In this, the acetylene-oxygen-spray powder mixture introduced is detonated by means of an ignition spark. The shock wave arising in the tube accelerates the spray particles. These are heated in the flame front and impinge with high particle velocity in a directed jet on a prepared piston surface. After each detonation, the combustion chamber and the tube are cleaned by flushing with nitrogen.

In plasma spraying, the pulverulent spraying additive is melted in or outside the spray gun by means of a plasma jet and flung onto the piston surface. The plasma is generated by an electric arc which burns in bundled form in argon, helium, nitrogen, hydrogen or in a mixture of these gases. The gases are in this way dissociated and ionized, they reach high flow velocities and on recombination pass their heat energy to the spray particles. A plasma flame having a temperature up to 20 000° C. is formed. The electric arc is produced between the electrode and the nozzle. As a result of the high temperatures, ceramic materials, in particular, can also be processed.

The electric arc does not transfer, i.e. it burns within the spray gun between a centrally arranged electrode (cathode) and the water-cooled spray nozzle which forms the anode. The process is employed in a normal atmosphere (APS—atmospheric plasma spraying), in a protective gas stream, i.e. in an inert atmosphere of, for example, argon, under reduced pressure or under water. A specifically shaped nozzle attachment also enables a high-velocity plasma to be produced.

Ceramic coatings are predominantly applied to the piston surface by means of atmospheric plasma spraying (APS).

Spray materials for coating piston surfaces, for example materials based on aluminum oxide (Al2O3), chromium oxide (Cr2O3), titanium oxide (TiO₂) and zirconium oxide (ZrO₂), are used.

In laser spraying processes, a pulverulent spraying additive is introduced into the laser beam via a suitable powder nozzle. Both the powder and also a minimal part of the piston surface (microrange) are melted by means of the laser radiation and the spraying additive introduced is metallurgically bound to the base material, viz. the piston surface. A protective gas serves to protect the melt bath.

In the electric arc spraying process, two spraying additives in the form of wires of the same type or different types are melted in an electric arc and flung by means of atomizer gas, for example compressed air, onto the prepared piston surface. Electric arc spraying is a high-performance wire spraying process, but can only be used for spraying electrically conductive materials.

When nitrogen or argon is used as atomizer gas, oxidation of the materials is largely prevented.

Metallic materials are, for example, applied to the piston surface by electric arc spraying. The conceivable range of materials encompasses most metals and very many mixtures, for example aluminum, copper (Cu/Al, Cu/Al/Fe), nickel (Ni/Al, Ni/Cr), molybdenum and zinc (Zn/Al).

The cold gas spraying process resembles high-velocity flame spraying. The kinetic energy, i.e. the particle velocity, is increased here and the thermal energy is reduced. It is thus possible to produce virtually oxide-free sprayed layers. This process has become known under the name CGDM (cold gas dynamic spray method).

The oxidation protection layer can also be applied to the piston surface by the metal coating system cold metal spray or cold spray system. The spraying additive material is accelerated to particle velocities of >1000 m/s by means of a gas jet which has been heated to about 600° C. and has an appropriate pressure and is applied as a continuous spray jet to the piston surface to be coated.

Studies have shown that layers produced by this process have extremely good adhesive pore strengths and are extraordinarily impermeable. While the powder used in the spraying process has to be heated to above its melting point in the hitherto customary thermal spraying processes, in the case of cold gas spraying it is heated to only a few hundred degrees. Oxidation of the sprayed material and the oxide content of the sprayed-on layer are thus considerably lower. Coated substrates display no materials changes caused by the action of heat.

Plasma application welding (PTA) using powder under a transferred electric arc. In the PTA process, the piston surface is partially melted. A high-density plasma arc serves as heat source and metal powder is used as applied material. The electric arc is formed between a permanent electrode and the workpiece. In the transferred electric arc, the plasma is generated in a plasma gas, for example argon, helium or argon/helium mixtures, between the central tungsten electrode (−) and the water-cooled anode block. The powder is brought to the burner by means of a carrier gas, is heated in the plasma jet and applied to the piston surface. Here, it melts completely in the melt bath on the substrate.

The entire process takes place in a protective gas atmosphere, for example argon or an argon/hydrogen mixture.

The PTA process makes it possible to achieve a low degree of mixing (5-10%), a small heat influence zone, a high application rate (up to 20 kg/h), genuine metallurgical adhesion between the substrate and the layer, and thus completely impermeable layers, and also flexibility of the alloying elements.

The application welding powders predominantly used can be classified as nickel-based, cobalt-based and iron-based alloys.

As an alternative or in addition, an oxidation protection layer is formed on the piston surface, viz. the substrate, by laser application welding. The material to be applied is fed as powder, wire or ribbon to the process. The surface of the material to be coated is partially melted. Virtually any material can be applied. Examples are free-flowing alloys (NiCrBSi), nickel-based alloys such as NiWC (nickel-tungsten carbide) or Deloro Stellite®, for example. With its constituents cobalt, chromium, molybdenum, tungsten and nickel, Stellite® is extremely resistant to corrosion, wear and heat. A greater proportion of dissolved chromium in the alloy additionally increases the corrosion resistance and thus also the oxidation resistance of the piston surface. Layer thicknesses in the range from 20 to 300 μm are applied here. The layers usually do not have to be processed further. Pretreatment of the substrate, for example by abrasive particle blasting processes such as alumina blasting, is not necessary.

Laser application welding using welding additive materials in powder and wire form is also referred to as direct metal deposition (DMD) or laser metal deposition (LMD).

As an alternative or in addition, the oxidation protection layer is produced by cold gas spraying on the substrate. In process, the material to be sprayed is introduced in powder form. The layers are very impermeable and the particles are barely oxidized during coating. Virtually any material, for example, titanium and titanium alloys or nickel-based alloys, c-BN (cubic boron nitride, β-boron nitride) with NiCrAl (nickel-chromium-aluminum), NiCr (nickel-chromium), NiAl (nickel-aluminum), CuAl (aluminum bronze) or MCrAlY powder, can be applied. Typical layer thicknesses are in the range of 20-300 μm. The component is barely heated during coating. CBN is the second-hardest known material after diamond. In contrast to diamond, CBN does not transfer any carbon to steel under the action of heat, and is therefore particularly suitable for surface coating of steel pistons. Superalloys of the MCrAlY type (metal-chromium-aluminum-yttrium; M=metal such as nickel (Ni) or cobalt (Co)) are high-temperature alloys which form aluminum oxide layers by selective oxidation and thus form oxidation protection on the piston surface. Nickel-cobalt-chromium-aluminum-yttrium (NiCoCrAlY) or cobalt-nickel-chromium-aluminum-yttrium (CoNiCrAlY) materials offer good resistance to oxidation.

Furthermore, the application of a layer, in particular, an oxidation protection layer, is carried out by thermal spraying (plasma, HVOF, electric arc, flame spraying processes) in a further embodiment. Here, the coating material is supplied as powder, wires, suspensions or rods. The coating can be built up as a single layer based on the coating material (monolayer). The use of various coatings or a combination of various coating materials, such as a bonding agent (e.g. NiCr, NiAl), which simultaneously also represents hot gas corrosion protection (MCrAlY), and a TBC (thermal barrier coating), for example, yttrium-stabilized zirconium oxide (Y—ZrO), can lead to a multilayer coating structure.

Thermal barrier coatings (TBC) reduce heat transfer and insulate the substrate. The layer systems deposited on piston surfaces preferably consist of two components, namely a bonding layer which functions as oxidation barrier and consists of a metallic material, for example MCrAlY and also a covering layer composed of a ceramic material, for example, yttrium-stabilized zirconium oxide (YSZ).

Depending on the coating process, Ni-based alloys or MoSi2/SnAl (molybdenum-silicon dioxide/zinc-aluminum) can also be applied. The layers can be densified and metallurgically bonded according to requirements (adhesion, impermeability to gas) by means of electron beam, WIG processes, diffusion heat treatment, induction heat treatment, laser, etc. (materials groups similar to electrochemical coating). Steels having high Cr, Si and Al contents (chromium, silicon and aluminum contents) form very impermeable oxide layers which protect the material against further oxidation. Typical layer thicknesses here are in the range of 20-300 μm.

The WIG process (tungsten-inert gas welding) is a protective gas welding process using inert protective gases as a protective gas. During the welding process, an electric arc burns between the workpiece and an infusible tungsten electrode and melts the base material and the additive material.

Welding processes can be implemented with a reasonable outlay in terms of apparatus in order to apply oxidation protection layers to piston crowns. Thus, for example, laser application welding processes or tungsten-inert gas welding processes are suitable for producing oxidation protection layers because of the small outlay in terms of apparatus.

Diffusion heat treatment serves to eliminate or reduce concentration differences, for example, crystal segregations or microstructural heterogeneities, in the piston or the piston surface. Based on the principle that high temperatures favor diffusion, the heat treatment is carried out at temperatures in the range from 1000° C. to 1200° C. Homogenization of the piston surface increases its oxidation resistance.

Induction heat treatment or induction hardening mainly brings workpieces having complicated shapes, for example, pistons or piston surfaces, to the required hardening temperature merely in particular regions (partial hardening) in order for them to be subsequently quenched.

Heat treatment processes contribute, in particular, to homogenization of the oxidation protection layer and can therefore be combined with other processes mentioned in the present text. Thus, for example, diffusion heat treatment processes or induction heat treatment processes are particularly suitable for homogenization of the oxidation protection layer and can therefore be used individually or in combination with other processes for producing an oxidation protection layer.

It is likewise possible to impregnate or seal the layers after spraying. Here, a sealer is applied and this then penetrates into and closes the voids in the sprayed layer and thus prevents crack corrosion or under-layer corrosion.

As an alternative or in addition, coatings composed of aluminum or aluminum alloys, preferably with the alloying elements silicon (e.g. AlSi12), copper and/or magnesium, which form oxidation-resistant protective layers having layer thicknesses of from 5 to 200 μm by formation of iron aluminides and/or stable iron-aluminum mixed oxides (preferably of the spinel type, e.g. hercynite FeO Al2O3 or FeAl2O4 or pleonast MgAl2O4) can be used for forming an oxidation protection layer. The application of aluminum (or the aluminum alloy) to the piston crown can be effected by one of the processes as described above, by means of a dipping bath (alfin bath) or by application of an aluminum-containing surface coating or a suspension. Depending on the application method, improved layer formation and adhesion can be achieved under some circumstances by means of subsequent, targeted, brief heating of the piston crown, preferably to temperatures above 660° C. (Al melting point). This heating can be effected, for example, by laser treatment, inductive heating, by means of a gas burner or the like, with the entry of oxygen or in the simplest case also atmospheric oxygen assisting the formation of the protective, stable mixed oxides.

The oxidation protection layer is particularly advantageously produced by coatings composed of, in particular, pure aluminum or of aluminum alloys. Such an alloy can, for example, form iron aluminides and/or stable iron-aluminum mixed oxides (preferably of the spinel type). The application of aluminum or the aluminum alloy to the piston crown can be effected by one of the processes as described above or by means of a dipping bath (alfin bath) or by application of an aluminum-containing surface coating or a suspension.

The alfin process provided as an alternative for forming an oxidation protection layer on the surface of a piston for internal combustion engines is a bonding casting process for metallic joining of steel or cast iron to aluminum or aluminum alloys. This Al-Fin process serves for bonding casting of aluminum (Al) and alloys to steel or cast iron. The piston components to be joined are firstly cleaned, preheated in a salt melt and dipped into liquid aluminum (830 to 880° C.). The intermetallic iron-aluminum layer formed is firmly joined to the base material and assists alloy formation and adhesion when aluminum materials are subsequently cast around it as oxidation protection layers. The Al-Fin process makes particularly good bonding between iron alloys and aluminum alloys possible.

The coatings composed of aluminum or of at least one aluminum alloy are produced at least on the piston crown of the piston by a process as described above, by means of a dipping bath (alfin bath), by application of an aluminum-containing surface coating and/or a suspension.

The production of a metallic bond between substrate and deposited layer can be effected by an additional thermal treatment in a second process step, for example by means of laser, WIG, electron beam or inductively.

In the production of an oxidation protection layer on the surface of a piston, a process step for preparing the surface can be carried out beforehand. The preparation of the piston surface can be effected by cleaning and/or pretreatment. In the case of cleaning, impurities are removed from the piston surface without influencing the substrate material. Pretreatment, on the other hand, serves to optimize the efficiency of the process for producing an oxidation protection layer on the piston surface. For pretreatment, it is possible to use processes which treat the appropriate piston surface in such a way that its surface properties are improved, for example in respect of adhesion of the oxidation protection layer. A material-changing pretreatment is also referred to as activation. For example, the piston surface is roughened in order to allow an increase in the surface area or allow microintermeshing of the oxidation protection layer as a result of the undercuts formed and to increase mechanical adhesion. Furthermore, the surface energy can be increased, which is also referred to as increasing the specific adhesion.

The preparation of the piston surface can be carried out by abrasive mechanical processes such as grinding, brushing or particle blasting processes. In these processes, part of the piston surface can also be removed. At least this removed part of the piston surface to be coated can be built up again by the oxidation protection layer to be produced by a process as mentioned in the present text.

The preparation of the piston surface can also be effected by chemical pretreatment methods such as etching or pickling, for example.

Furthermore, the preparation of the piston surface can also be carried out by physical processes such as flaming, plasma, corona or laser pretreatment processes, for example.

In the preparation of the piston surface for use of at least one process as mentioned in the present text for producing an oxidation protection layer by cleaning, it is necessary to remove, for example, impurities from the preceding production steps (for example forming processes), e.g. coolants and/or lubricants (CL), corrosion protection oils, fluxes, scale, graphite, metal soaps, sulfonates, mineral oils, inorganic soaps, metal oxides, metal salts, dust and/or turnings.

The production of an oxidation protection layer by one of the processes mentioned in the present text can be carried out on a piston blank, a region of the piston or on the entire surface of the piston for an internal combustion engine. Preference is given to at least the piston crown having an oxidation protection layer.

All processes mentioned in the present text for producing an oxidation protection layer on the surface of a piston for internal combustion engines can be used either individually or in virtually any combination for producing an oxidation protection layer on the surface of a piston for internal combustion engines. A combination of processes for producing an oxidation protection layer on the surface of a piston for internal combustion engines enables multilayer systems to be deposited or built up on the surface of a piston.

The formation of the oxidation protection layer as multilayer system on the piston surface makes it possible to take account of the requirements which the oxidation protection layer has to meet.

When the oxidation protection layer on the piston surface is configured as a multilayer system, it is possible to use advantageous materials as basis for the piston.

When the oxidation protection layer is in the form of a multilayer system, at least two layers are applied to the piston surface. These at least two layers can have the same chemical and physical properties, but they can also have chemically and/or physically differing properties.

The processes for producing an oxidation protection layer can be used either individually or in virtually any combination. When processes are combined, multilayer oxidation protection layers can be formed. These multilayer oxidation protection layers can consist of identical substances or different substances.

In accordance with the present process, for a piston, especially a steel piston for an internal combustion engine, having a piston crown that is part of a combustion chamber, at least the piston crown has an oxidation protection layer.

The application of an oxidation protection layer on the piston crown reduces or even prevents oxidative attack on the piston material in the region of the combustion depression. It is thus possible for the piston to be made of other materials. Selection of other materials enables the costs to be reduced.

The abovementioned coating materials and materials classes can be selected according to the requirements which the oxidation protection layer has to meet. Combinations of the various coating materials and materials classes are also possible in order to form a suitable oxidation protection layer on the surface of the piston crown.

What is claimed:

1. The process for producing a piston, in particular a steel piston for an internal combustion engine, as claimed in claim 23 characterized in that the oxidation protection layer is produced by a physical process for deposition of coating materials from a gas phase (physical vapor deposition—PVD) at least on the piston crown of the piston.

2. The process for producing a piston, in particular a steel piston for an internal combustion engine, as claimed in claim 23 characterized in that the oxidation protection layer is produced by a process for chemical vapor deposition (CVD) at least on a piston crown of the piston.

3. The process for producing a piston, in particular a steel piston for an internal combustion engine, as claimed in claim 23 characterized in that the oxidation protection layer is produced at least on the piston crown of the piston by a process of electrochemical metal deposition (ECD—electrochemical deposition).

4. The process for producing a piston, in particular a steel piston for an internal combustion engine, as claimed in claim 23 characterized in that the oxidation protection layer is produced by a thermal spraying process at least on the piston crown of the piston.

5. The process for producing a piston, in particular a steel piston for an internal combustion engine, as claimed in claim 23 characterized in that the oxidation protection layer is produced by a laser application welding process or tungsten-inert gas welding process at least on the piston crown of the piston.

6. The process for producing a piston, in particular a steel piston for an internal combustion engine, as claimed in claim 23 characterized in that the oxidation protection layer is produced by a diffusion heat treatment process or induction heat treatment process at least on the piston crown of the piston.

7. The process for producing a piston, in particular a steel piston for an internal combustion engine, as claimed in claim 23 characterized in that the oxidation protection layer is produced by means of coatings composed of aluminum or of at least one aluminum alloy on a region of the piston.

8. The process for producing a piston, in particular a steel piston for an internal combustion engine, as claimed in claim 7, characterized in that the aluminum alloy forms iron aluminides and/or stable iron-aluminum mixed oxides.

9. The process for producing a piston, in particular a steel piston for an internal combustion engine, as claimed in claim 7, characterized in that the coatings composed of aluminum or of at least one aluminum alloy are produced at least on the piston crown of the piston by a process by means of a dipping bath by application of an aluminum-containing surface coating and/or a suspension.

10. The process for producing a piston, in particular a steel piston for an internal combustion engine, as claimed in claim 23 characterized in that an oxidation protection layer is produced by a combination of at least two of gas phase vapor deposition, chemical vapor deposition, electrochemical metal deposition, thermal spraying process, a laser welding process, a tungsten-inest gas welding process, a diffusion heat treatment process, an induction heating process and coating composed of aluminum or aluminum alloy.

11. A piston, in particular a steel piston for an internal combustion engine, having an oxidation protection layer at least in the region of the piston crown (2), characterized in that the oxidation protection layer has been produced by at least one of gas phase vapor deposition, chemical vapor deposition, electrochemical metal deposition; thermal spraying process, a laser welding process, a tungsten-inest gas welding process, a diffusion heat treatment process, an induction heating process and coating composed of aluminum or aluminum alloy.

12. The piston as claimed in claim 11, characterized in that the oxidation protection layer is formed from the substance class of nitrides or carbides.

13. The piston as claimed in claim 11, characterized in that the oxidation protection layer is formed by nickel, nickel-based alloys, chromium, chromium-based alloys, scale-resistant iron-based alloys or tungsten alloys and molybdenum alloys.

14. The piston as claimed in claim 11, characterized in that the oxidation protection layer consists of an NiCrBSi coating (nickel-chromium-boron-silicon coating).

15. The piston as claimed in claim 11, characterized in that the oxidation protection layer consists of oxides, including aluminum oxide (Al₂O₃), chromium oxide (Cr₂O₃), titanium oxide (TiO₂) or zirconium oxide (ZrO₂).

16. The piston as claimed in claim 11, characterized in that the oxidation protection layer consists of a nickel-based alloy including NiWC (nickel-tungsten carbide), NiCrAl (nickel-chromium-aluminum), NiCr (nickel-chromium), NiAl (nickel-aluminum) or Stellite® with its constituents cobalt, chromium, molybdenum, tungsten and nickel.

17. The piston as claimed in claim 11, 12, 13, 14, 15 or 16, characterized in that the oxidation protection layer is formed by CBN or MCrAlY.

18. The piston as claimed in claim 11, characterized in that the oxidation protection layer is made up of two layers, including a thermal barrier layer (TBC), and a covering layer composed of a ceramic material.

19. The piston as claimed in claim 11, characterized in that the oxidation protection layer consists of a MoSi₂/SnAl (molybdenum-silicon dioxide/zinc-aluminum) layer.

20. The piston as claimed in claim 11, characterized in that the oxidation protection layer is formed by coatings composed of aluminum or at least one aluminum alloy, preferably having the alloying elements silicon (e.g. AlSi₁₂), copper and/or magnesium, which form oxidation-resistant protective layers by formation of iron aluminides and/or stable iron-aluminum mixed oxides.

21. The piston as claimed in claim 11, characterized in that the oxidation protection layer has a thickness in the range from 3 μm to 300 μm.

22. The piston as claimed in claim 11, characterized in that the piston has a multilayer oxidation protection layer made up of at least two oxidation protection of gas phase vapor deposition, chemical vapor deposition, electrochemical metal deposition; thermal spraying process, a laser welding process, a tungsten-inest gas welding process, a diffusion heat treatment process, an induction heating process and coating composed of aluminum or aluminum alloy.

23. A process for producing a piston, in particular a steel piston for an internal combustion engine, characterized in that the oxidation protection layer is produced for deposition on a piston crown of the piston.
